(19) United States
(12) Patent Application Publication
(10) Pub. No.: US 2021/0325336 A1
(43) Pub. Date: Oct. 21, 2021

(54) FIELD EFFECT TRANSISTOR, GAS SENSOR, AND MANUFACTURING METHOD THEREOF

(71) Applicants: TOYOTA JIDOSHA KABUSHIKI KAISHA, Toyota-shi (JP); THE UNIVERSITY OF TOKYO, Tokyo (JP)

(72) Inventors: Junzo UKAI, Toyota-shi (JP); Taishi SHIOTSUKI, Tokyo (JP); Tsuyoshi MINAMI, Tokyo (JP); Yui SASAKI, Tokyo (JP)

(21) Appl. No.: 17/233,974

(22) Filed: Apr. 19, 2021

(30) Foreign Application Priority Data
Apr. 21, 2020 (JP) 2020-075290
Feb. 1, 2021 (JP) 2021-014413

(51) Int. Cl. G01N 27/414; H01L 51/05; H01L 51/00

(52) U.S. Cl. CPC G01N 27/4141; H01L 51/0525; H01L 51/055; H01L 51/0052; H01L 51/0566; H01L 51/0003; H01L 51/0545

(57) ABSTRACT

An object is to provide a field effect transistor using a metal organic framework film as a semiconductor layer and having a novel structure. This embodiment is a field effect transistor that includes a substrate, a source electrode, a drain electrode, a gate electrode, and a metal organic framework film as a semiconductor layer. The metal organic framework film has a stacked structure. A plurality of crystalline structures in which organic ligands having a π-conjugated skeleton and metal ions are coordinated to be developed in a planar direction of the substrate are stacked on the substrate via a π-π interaction in the stacked structure. The crystalline structures each have pores formed by the coordination of the organic ligands and the metal ions. The pores in the adjacent crystalline structures communicate with one another in a film thickness direction in the stacked structure. The field effect transistor is a top-contact type.

### CROSS REFERENCE TO RELATED APPLICATIONS

The present application claims priority from Japanese patent application 2020-75290 filed on Apr. 21, 2020 and Japanese patent application JP 2021-014413 filed on Feb. 1, 2021, the entire content of which is hereby incorporated by reference into this application.

### BACKGROUND

### Technical Field

The present disclosure relates to a field effect transistor, a gas sensor, and a manufacturing method thereof.

### Background Art

Examples of metal organic framework (MOF) include a material having a semiconductor property, and the material is applicable as a semiconductor layer of a field effect transistor (also referred to as a FET). Among the metal organic framework, there is a material having a gas adsorption capacity in addition to the semiconductor property, and the material can be used for a gas sensor.

For example, WO20161185679 discloses a chemical sensor that includes a field effect transistor, a detection region disposed on the field effect transistor, and a sensitive film disposed in the detection region. The sensitive film includes a metal organic framework. WO2016/185679 describes that the chemical sensor allows accurately detecting a detection target component in a sample.

### SUMMARY

As described above, the field effect transistor to which the metal organic framework film is applied is applicable to various devices including the gas sensor, and development of a further novel field effect transistor has been desired. Especially, for example, a field effect transistor that allows achieving low-voltage driving has been demanded.

The present disclosure provides a field effect transistor using a metal organic framework film as a semiconductor layer and having a novel structure.

Exemplary aspects of embodiments will be described as follows.

(1) A field effect transistor comprises a substrate, a source electrode, a drain electrode, a gate electrode, and a metal organic framework film as a semiconductor layer. The metal organic framework film has a stacked structure. A plurality of crystalline structures in which organic ligands having a π-conjugated skeleton and metal ions are coordinated to be developed in a planar direction of the substrate are stacked on the substrate via a π-π interaction in the stacked structure. The crystalline structures each have pores formed by the coordination of the organic ligands and the metal ions. The pores in the adjacent crystalline structures communicate with one another in a film thickness direction in the stacked structure. The field effect transistor is a top-contact type.
(2) The field effect transistor according to (1), wherein the field effect transistor is a bottom-gate and top-contact type.
(3) In the field effect transistor according to (1) or (2), then π-conjugated skeleton includes at least one aromatic ring.
(4) In the field effect transistor according to any one of (1) to (3), the π-conjugated skeleton has a polycyclic aromatic hydrocarbon structure.
(5) In the field effect transistor according to any one of (1) to (4), the organic ligand has a three-fold rotational symmetry.
(6) In the field effect transistor according to any one of (1) to (5), the metal ions are metal ions capable of having a coordination number of four or more.
(7) In the field effect transistor according to any one of (1) to (6), the gate electrode is an aluminum electrode.
(8) In the field effect transistor according to (7), the aluminum electrode has a surface on which an aluminum oxide as a gate insulating layer is formed.
(9) In the field effect transistor according to any one of (1) to (8), the metal organic framework film is formed by a LBL method. The LBL method includes applying a metal ion-containing solution containing the metal ions over the substrate and applying an organic ligand-containing solution containing the organic ligands over the substrate.
(10) A gas sensor comprises the field effect transistor according to any one of (1) to (9).
(11) A method of manufacturing the field effect transistor according to any one of (1) to (8) includes forming the metal organic framework film by LBL method including: applying a metal ion-containing solution containing the metal ions over the substrate; and applying an organic ligand-containing solution containing the organic ligands over the substrate.

The present disclosure allows providing the field effect transistor using the metal organic framework film as the semiconductor layer and having the novel structure.

### BRIEF DESCRIPTION OF THE DRAWINGS

FIG. 1A is a schematic cross-sectional view for describing a basic structure of a bottom-gate and top-contact field effect transistor 10 as one example of a field effect transistor of this embodiment;

FIG. 1B is a schematic cross-sectional view for describing a basic structure of a bottom-gate and bottom-contact field effect transistor 200 as one example of the field effect transistor;

FIG. 2A is an AFM image of a metal organic framework film obtained in Example 1;

FIG. 2B is an (enlarged) AFM image of the metal organic framework film obtained in Example 1;

FIG. 3 is a FE-SEM image of a cross-sectional surface of the metal organic framework film obtained in Example 1;

FIG. 4 is a FT-IR spectrum of the metal organic framework film obtained in Example 1;

FIG. 5 is a graph illustrating results of electrical resistance evaluation of the metal organic framework film obtained in Example 1;

FIG. 6A is a schematic cross-sectional process drawing for describing a manufacturing process of a (top-contact) field effect transistor of Example 2 or 3;

FIG. 6B is a schematic cross-sectional process drawing for describing the manufacturing process of the (top-contact) field effect transistor of Example 2 or 3 continuous from FIG. 6A;

FIG. 6C is a schematic cross-sectional process drawing for describing the manufacturing process of the (top-contact) field effect transistor of Example 2 or 3 continuous from FIG. 6B;

FIG. 6D is a schematic cross-sectional process drawing for describing the manufacturing process of the (top-contact) field effect transistor of Example 2 or 3 continuous from FIG. 6C;

FIG. 6E is a schematic cross-sectional process drawing for describing the manufacturing process of the (top-contact) field effect transistor of Example 2 or 3 continuous from FIG. 6D;

FIG. 6F is a schematic cross-sectional process drawing for describing the manufacturing process of the (top-contact) field effect transistor of Example 2 or 3 continuous from FIG. 6E;

FIG. 7A is a FT-IR spectrum of a particulate MOF obtained in Comparative Example 1:

FIG. 7B is a XRD spectrum of the particulate MOF obtained in Comparative Example 1;

FIG. 8A is a graph illustrating results of evaluation of transmission characteristics of a field effect transistor E1 obtained in Example 2;

FIG. 8B is a graph illustrating results of evaluation of output characteristics of the field effect transistor E1 obtained in Example 2;

FIG. 9 is a graph illustrating results of evaluation of transmission characteristics of a field effect transistor C1 obtained in Comparative Example 1;

FIG. 10A is a schematic cross-sectional process drawing for describing a manufacturing process of a (bottom-contact) field effect transistor in Comparative Example 2;

FIG. 10B is a schematic cross-sectional process drawing for describing the manufacturing process of the (bottom-contact) field effect transistor of Comparative Example 2 continuous from FIG. 10A;

FIG. 10C is a schematic cross-sectional process drawing for describing the manufacturing process of the (bottom-contact) field effect transistor of Comparative Example 2 continuous from FIG. 10B;

FIG. 10D is a schematic cross-sectional process drawing for describing the manufacturing process of the (bottom-contact) field effect transistor of Comparative Example 2 continuous from FIG. 10C;

FIG. 11 is a graph illustrating results of evaluation of transmission characteristics of a field effect transistor E2 (Example 3); and

FIG. 12 is a graph illustrating results of evaluation of transmission characteristics of a field effect transistor C2 (Comparative Example 2).

### DETAILED DESCRIPTION

This embodiment is a field effect transistor that includes a substrate, a source electrode, a drain electrode, a gate electrode, and a metal organic framework film as a semiconductor layer. The metal organic framework film has a stacked structure. A plurality of crystalline structures in which organic ligands having a π-conjugated skeleton and metal ions are coordinated to be developed in a planar direction of the substrate are stacked on the substrate via a π-π interaction in the stacked structure. The crystalline structures each have pores formed by the coordination of the organic ligands and the metal ions. The pores in the adjacent crystalline structures communicate with one another in a film thickness direction in the stacked structure. The field effect transistor is a top-contact type.

This embodiment can provide the field effect transistor using the metal organic framework film as the semiconductor layer and having the novel structure. Additionally, the field effect transistor according to this embodiment can be driven at a low voltage in some embodiments.

Hereinafter, the embodiments will be described with reference to the drawings, but the present disclosure is not limited to the following embodiments.

1. Field Effect Transistor

The field effect transistor of this embodiment includes the metal organic framework film of this embodiment, which will be described later in detail, as the semiconductor layer. The field effect transistor of this embodiment includes the substrate, the source electrode, the drain electrode, and the gate electrode, in addition to the semiconductor layer. The field effect transistor of this embodiment is the top-contact type. The field effect transistor of this embodiment is used as an insulated gate FET in which between a gate and a channel is insulated in some embodiments.

A thickness of the field effect transistor of this embodiment excluding the substrate is not especially limited, but is, for example, from 150 to 350 nm.

The field effect transistor of this embodiment includes the substrate, the gate electrode on the substrate, the metal organic framework film, a gate insulating layer between the gate electrode and the metal organic framework film, and the source electrode and the drain electrode disposed in contact with the metal organic framework film and coupled via the metal organic framework film in some embodiments. In the field effect transistor, the metal organic framework film is disposed adjacent to the gate insulating layer.

The field effect transistor of this embodiment has the top-contact type structure. Examples of the top-contact type include a bottom-gate and top-contact type, a top-gate and top-contact type, or the like. The field effect transistor of this embodiment is the top-contact type and the bottom-gate and top-contact type in some embodiments. In this embodiment, the top-contact field effect transistor allows further effective driving at a low voltage. It is inferred that this is because adhesiveness between the semiconductor layer and the electrodes is high in the top-contact structure and this allows achieving mobility higher than that of the bottom-contact structure. Note that this embodiment is not limited to the inference.

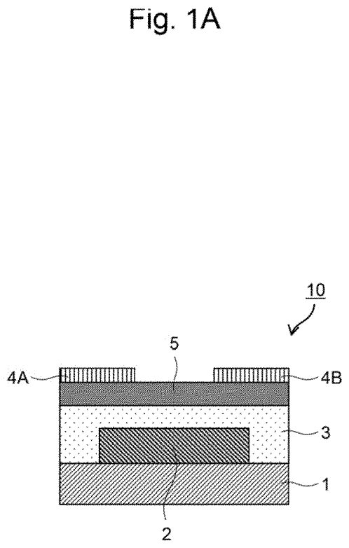

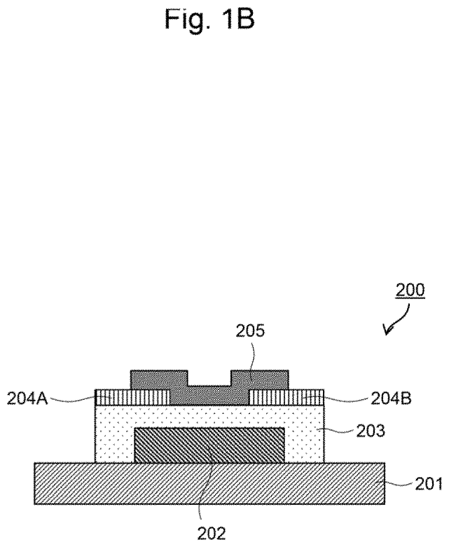

FIG. 1A is a schematic cross-sectional view for describing a basic structure of a bottom-gate and top-contact field effect transistor 10 as one example of the field effect transistor of this embodiment. Meanwhile, FIG. 1B is a schematic cross-sectional view for describing a basic structure of a bottom-contact (bottom-gate and bottom-contact) field effect transistor 200, which is not this embodiment.

As illustrated in FIG. 1A, the (bottom-gate and top-contact) field effect transistor 10 includes a substrate 1, a gate electrode 2, a gate insulating layer 3, a metal organic framework film 5 as a semiconductor layer, and a source electrode 4A and a drain electrode 4B in this order. The structure may be covered with a sealing layer (not illustrated). For example, the sealing layer can be made of a material with gas permeability.

The (bottom-gate and bottom-contact) field effect transistor 200 differs from the field effect transistor 10 in an aspect of stacking. As illustrated in FIG. 1B, the (bottom-gate and bottom-contact) field effect transistor 200 includes a substrate 201, a gate electrode 202, a gate insulating layer 203, a source electrode 204A and a drain electrode 204B, and a metal organic framework film 205 as a semiconductor layer in this order.

The following will describe the substrate, the gate electrode, the gate insulating layer, the source electrode, the drain electrode, and the metal organic framework film.

(Substrate)

The substrate serves as supporting the gate electrode, the source electrode, the drain electrode, and the like.

The type of the substrate is not especially limited, but examples of which include a plastic substrate, a silicon substrate, a glass substrate, or a ceramic substrate. Among them, from aspects of applicability to the devices and the cost, the glass substrate or the plastic substrate are used in some embodiments.

(Gate Electrode)

The gate electrode is not especially limited, but, for example, a general electrode used as a gate electrode of a field effect transistor can be used.

The material of the gate electrode is not especially limited, but examples of which include a metal, such as gold, silver, aluminum, copper, chrome, nickel, cobalt, titanium, platinum, magnesium, calcium, barium, or sodium; a conductive oxide, such as InO₂, SnO₂, or indium tin oxide (ITO); a conductive polymer, such as polyaniline, polypyrrole, polythiophene, polyacetylene, or polydiacetylene; a semiconductor, such as silicon, germanium, or gallium arsenide; a carbon material, such as fullerene, carbon nanotube, or graphite; or the like. Among them, the metal is used in some embodiments and aluminum is used in some embodiments. Since the aluminum has a sublimation temperature lower than those of the other metals, the film can be formed at a mild condition. Additionally, a metal oxide film (aluminum oxide film) can be formed on the metal electrode surface under the mild condition. Furthermore, since the obtained aluminum oxide film has a large electrostatic capacity, the low-voltage driving can be effectively achieved.

A method for forming the gate electrode is not especially limited, but includes, for example, a method that performs vapor deposition or sputtering of an electrode material on the substrate and a method that applies a composition for electrode formation containing an electrode material. To pattern the electrode, examples of the patterning method include a print method, such as ink-jet printing, screen-printing, offset printing, or letterpress printing (flexography), a photolithography method, or a mask vapor deposition.

(Gate Insulating Layer)

As long as the layer has an insulating property, the gate insulating layer is not especially limited. The gate insulating layer may be a single layer or may be multi-layers.

The material of the gate insulating layer is not especially limited, but examples of which include an inorganic oxide, such as aluminum oxide, silicon nitride, silicon dioxide, or titanium oxide; a polymer, such as polymethyl methacrylate, polystyrene, polyvinylphenol, melamine resin, polyimide, polycarbonate, polyester, polyvinyl alcohol, polyvinyl acetate. polyurethane, polysulfone, polybenzoxazole, polysilsesquioxane, epoxy resin, or phenolic resin. As the material of the gate insulating layer, one kind may be used alone or two kinds or more may be used in combination. Among them, in terms of uniformity of films, the inorganic oxide is used in some embodiments and aluminum oxide is used in some embodiments. To achieve sufficient electric charge induction to the semiconductor by application of the low voltage to the gate electrode, it is desired to increase the electrostatic capacity of the gate insulating film. Therefore, introduction of the aluminum oxide film having the large electrostatic capacity to the top-contact structure allows achieving the low-voltage driving. The aluminum oxide film can be formed by oxidizing aluminum under a comparatively mild condition (for example, oxygen plasma irradiation energy; about 150 W for an irradiation period from several minutes to several ten minutes). Since the aluminum oxide film has excellent insulating property even with the thin film, the aluminum oxide film can contribute to low-voltage driving. Furthermore, to manufacture a MOF transistor by the top-contact structure, a hydroxyl group present in the surface of the aluminum oxide film bonds to metal ions and serves as a base to construct a MOF film.

A method for forming the gate insulating layer is not especially limited, but includes, for example, a method that applies a composition for gate insulating layer formation containing the above-described material over the substrate on which the gate electrode has been formed and a method that performs vapor deposition or sputtering of the material. Besides, the surface of the metal as the gate electrode is oxidized to form an oxide, and the oxide can be used as the gate insulating layer. For example, the gate electrode is formed with aluminum, and the surface of the aluminum is oxidized into aluminum oxide by reactive ion etching or the like, thus allowing forming the insulating layer.

(Source Electrode and Drain Electrode)

The source electrode is an electrode into which a current flows from outside through a wiring. The drain electrode is an electrode that sends a current to outside through a wiring.

As the material to form the source electrode and the drain electrode, the material the same as the above-described electrode material forming the gate electrode can be used. Among them, the metal is used in some embodiments, and gold or silver is used in some embodiments.

An interval (gate length) between the source electrode and the drain electrode can be appropriately determined, but examples of which include 200 μm or less in some embodiments and 100 μm or less in some embodiments. A gate width can be appropriately determined, and examples of which include 5000 μm or less in some embodiments and 2000 μm or less in some embodiments. Further, a ratio of the gate width W to the gate length L is not especially limited, but examples of which include the ratio W/L of 10 or more in some embodiments and 20 or more in some embodiments.

The method for forming the source electrode and the drain electrode is not especially limited, but includes, for example, a method that performs vapor deposition or sputtering of an electrode material on the substrate on which the gate electrode, the gate insulating layer, and the metal organic framework film in some cases, have been formed, a method that applies or prints a composition for electrode formation, and the like. For patterning, the patterning method includes the method the same as the above-described method for forming the gate electrode.

(Metal Organic Framework Film)

The field effect transistor of this embodiment includes the metal organic framework film as the semiconductor layer. The metal organic framework film has a stacked structure in which a plurality of crystalline structures, in which organic ligands having a π-conjugated skeleton and metal ions are coordinated to be developed in the plane direction of the substrate, are stacked on the substrate via a π-π interaction. The crystalline structures each have pores formed by the coordination of the organic ligands and the metal ions. In the stacked structure, the pores in the adjacent crystalline structures communicate with one another in the film thickness direction to form communication pores.

The metal organic framework film in this embodiment can be formed by Layer By Layer (LBL) method using the organic ligands having the π-conjugated skeleton and the metal ions. The LBL method is a method that applies a metal ion-containing solution containing metal ions and an organic ligand-containing solution containing organic ligands over a region where the metal organic framework film is to be formed in alternation by drop casting or the like to form thin films. The LBL method using the organic ligands having the π-conjugated skeleton and the metal ions allows obtaining the metal organic framework film of this embodiment in some embodiments. That is, the metal organic framework film formed by LBL method contains the plurality of crystalline structures in which the organic ligands having the π-conjugated skeleton and the metal ions are coordinated to be developed in the planar direction. In the crystalline structures, the pores formed by the coordination of the organic ligands having the π-conjugated skeleton and the metal ions are formed. The plurality of crystalline structures in which the organic ligands and the metal ions are coordinated to be developed in the planar direction are stacked such that the pores in the crystalline structures are communicated in the film thickness direction by the π-π interaction of the organic ligands to form the communication pores. That is, the plurality of crystalline structures in which the organic ligands and the metal ions are coordinated to be developed in the planar direction are stacked in the film thickness direction to form the metal organic framework film. In the metal organic framework film in this embodiment, delocalized π electrons are present. In conduction, the delocalized n electrons flow out and are conducted through the molecules, which entirely have negative charge. Additionally, the communication pores in the metal organic framework film can, for example, have a property of adsorbing a gas. The adsorption of the gas to the communication pores changes a resistance of the metal organic framework film.

The organic ligands used to form the metal organic framework film have the π-conjugated skeleton. One kind of the organic ligand may be used alone, or two kinds or more of the organic ligands may be used in combination. From aspects of uniformity of the film and the communication pores, one kind of the organic ligand is used alone in some embodiments.

The π-conjugated skeleton constituting the organic ligand is formed by including at least one aromatic ring in some embodiments. In this embodiment, the skeleton means a part other than coordinating functional groups in the organic ligand in some embodiments.

The coordinating functional groups of the organic ligand are two or more, three or more, four or more, five or more, and six or more in some embodiments. Examples of the coordinating functional group include a hydroxy group (hydroxyl group), a carboxylic acid group, or an amine group.

The π-conjugated skeleton of the organic ligand has a polycyclic aromatic hydrocarbon structure in some embodiments. Examples of the polycyclic aromatic hydrocarbon structure include a triphenylene structure, a pyrene structure, a perylene structure, or a mellitic triimide structure. In a case where the π-conjugated skeleton is the polycyclic aromatic hydrocarbon structure, the crystalline structure in which the organic ligands and the metal ions are coordinated to be developed in the planar direction can be easily formed by LBL method.

The organic ligand has a three-fold rotational symmetry or a four-fold rotational symmetry in some embodiments. The three-fold rotational symmetry means that when a structural formula of the organic ligand is rotated by 120° with its center as the axis, the structure becomes the same as the original structure. Similarly, the four-fold rotational symmetry means that when the structural formula of the organic ligand is rotated by 90° with its center as the axis, the structure becomes the same as the original structure.

An example of the organic ligand having the three-fold rotational symmetry includes the following compounds.

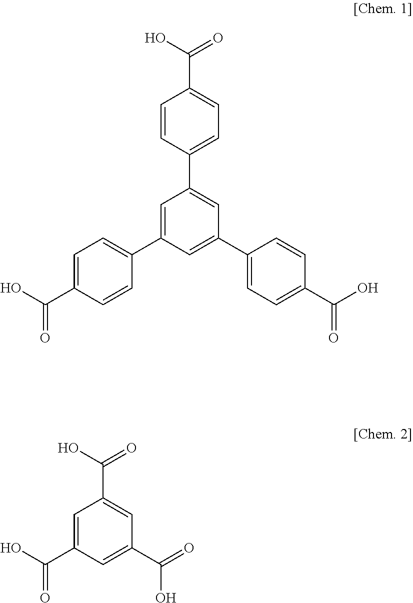 [SMILES: O=C(O)c1ccc(-c2cc(-c3ccc(C(=O)O)cc3)cc(-c3ccc(C(=O)O)cc3)c2)cc1 ; O=C(O)c1cc(C(=O)O)cc(C(=O)O)c1]

Even rotated by 120°, these compounds do not differ in positions of each part of the skeleton or each coordinating functional group between before and after the rotation. Therefore, the compounds have the three-fold rotational symmetry.

The organic ligand has the π-conjugated skeleton in the polycyclic aromatic hydrocarbon structure and has the three-fold rotational symmetry in some embodiments. In this case, the crystalline structure in which the organic ligands and the metal ions are coordinated to be developed in the planar direction can be easily formed by LBL method, and the metal organic framework film that exhibits high carrier mobility and is stable under the atmosphere can be obtained. A large number of recognition points of the organic ligands can contribute to extension of conjugated regions, and a molecular structure having high rigidity and the conjugated region can produce a regular three-dimensional structure.

An example of the organic ligand having the π-conjugated skeleton in the polycyclic aromatic hydrocarbon structure and having the three-fold rotational symmetry includes 2,3,6,7,10,11-hexahydroxytriphenylene (HHTP).

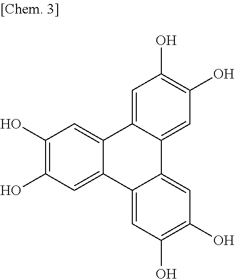 [SMILES: Oc1cc2c3cc(O)c(O)cc3c3cc(O)c(O)cc3c2cc1O]

The metal ions used to form the metal organic framework film are not especially limited and can be appropriately selected according to the kind of the organic ligand. For example, the metal ions are metal ions capable of having four or more-coordination in some embodiments. Examples of the metal ions capable of having four or more-coordination, that is, the metal ions capable of having a coordination number of four or more include copper ions, nickel ions, zinc ions, cobalt ions, or cadmium ions. The metal ions may be present as clusters.

In this embodiment, as the organic ligands, the organic ligands having the π-conjugated skeleton in the polycyclic aromatic hydrocarbon structure and having the three-fold rotational symmetry are used, and as the metal ions, the metal ions capable of having four-coordination are used in some embodiments. In one embodiment, the three metal ions are coordinated to one molecule of the organic ligand having the three-fold rotational symmetry. An example of the metal ions capable of having four-coordination includes copper ions.

The metal organic framework film formed using the HTTP as the organic ligands and using the metal ions capable of having four-coordination as the metal ions includes the structural unit of the following Formula (I).

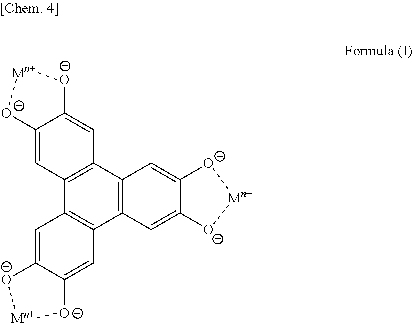

(In the formula, M denotes the metal ions capable of having four-coordination.)

In the structural unit of Formula (I), M is, for example, a copper ion. In the structural unit of Formula (I), the three metal ions are coordinated to one organic ligand (HHTP). The respective metal ions are also coordinated to another organic ligand (not illustrated), and the organic ligands and the metal ions are coordinated such that the structural unit of Formula (I) is developed in the planar direction to form the crystalline structure. The crystalline structures formed such that the organic ligands and the metal ions are coordinated to be developed in the planar direction are countlessly contained in the metal organic framework film. One crystalline structure is stacked with another crystalline structure adjacent in the upward direction or the downward direction by the π-π interaction in which the pores in the two crystalline structures are coupled to form the communication pores. The stacked body of the crystalline structures form the metal organic framework film.

For example, specifically, in the metal organic framework film formed by the combination of the HHTPs and the copper ions (Cu²⁺), Cu²⁺ are coordinated at three diol moieties of the HHTP and Cu²⁺ has four-coordination, and therefore Cu²⁺ are coordinated with two HHTPs. It is considered that, in addition to the two-dimensional film formation caused by the large number of coordinate bond points by the HHTPs, the π-π interaction expressed in the MOF formation in the perpendicular direction is combined to cause the MOF to exhibit the excellent semiconductor property.

The organic ligands may be added in a solution in a form of hydrate or salt.

While the film thickness of the metal organic framework film is not especially limited, for example, the film thickness is from 10 to 500 nm in some embodiments and from 20 to 200 nm in some embodiments. The film thickness of the metal organic framework film can be appropriately adjusted by, for example, the number of cycles of the application process, such as drop casting, during formation by LBL method.

While the application of the field effect transistor of this embodiment is not especially limited, for example, the field effect transistor can be used as a gas sensor. That is, with the field effect transistor of this embodiment, when the enclosed gas molecules are enclosed by the MOF film, their conductive properties change, thus providing a change to the semiconductor property. For example, an entrance of ammonia into the MO film changes the semiconductor property of the MOF film by unpaired electrons of the ammonia. It is anticipated that when the gas molecules enter the MOF film, a difference in a size or a molecular structure of the gas molecules exhibits different behaviors of the semiconductor property. Therefore, for example, it is considered that a combination of a pattern learning algorithm allows quantitatively identifying the kind of the gas molecules contained in the mixed gas.

2. Manufacturing Method of Field Effect Transistor

While the manufacturing method of the field effect transistor of this embodiment is not especially limited, as described above, the metal organic framework film in this embodiment can be formed by LBL method in some embodiments.

All of the gate electrode, the gate insulating layer, the source electrode, and the drain electrode can be manufactured or their films can be formed by the above-described methods.

The following will describe processes to form the metal organic framework film by LBL method.

In this embodiment, an application of a certain composite on the substrate includes, not only the aspect of directly applying the composite on the substrate, but also an aspect of applying the composite above the substrate via another layer disposed on the substrate. The other layer (the layer serving as the base of the metal organic framework film) over which the composite is applied is inevitably determined from the structure of the field effect transistor. The layer serving as the base of the metal organic framework film is, for example, the gate insulating layer in the case of the bottom-gate type.

To form the metal organic framework film by LBL method, first, the metal ion-containing solution containing metal ions is applied over the substrate, that is, over the layer (for example, the gate insulating layer) serving as the base and is dried (metal ion-containing solution applying process). The application may be performed once or may be performed multiple times. Next, the organic ligand-containing solution containing organic ligands is applied over the substrate and is dried (organic ligand-containing solution applying process). The application may be performed once or may be performed multiple times. By performing the metal ion-containing solution applying process and the organic ligand-containing solution applying process by a plurality of times in alternation allows forming the metal organic framework film in this embodiment. For example, “Ming-Shui Yao, et al. Layer-by-Layer Assembled Conductive Metal-Organic Framework Nanofilms for Room-Temperature Chemiresistive Sensing, Angew. Chem. Int., Ed. 2017, 56, 16510-16514” also describes the LBL method.

For example, the metal ion-containing solution can be prepared by dissolving a metallic salt containing the above-described metal ions into a solvent.

Examples of the metallic salt include metal acetate, metal formate, metal nitrate, metal sulfate, metal chloride, metal bromide, metal iodide, metal fluoride, metal carbonate, metal phosphate, metal sulfide, metal hydroxide, or the like, but the metallic salt is not limited to these. One kind of the metallic salt may be used alone or two kinds or more of the metallic salts may be used in combination.

The content of the metal ions in the metal ion-containing solution is not especially limited, but is, for example, from 1 to 50 mmol/L. The amount of application of the metal ion-containing solution is not especially limited, but is, for example, from 6×10⁻⁶ to 7×10⁻⁴ μl/μm².

The solvent used for the metal ion-containing solution is not especially limited and is appropriately selectable considering the kind and volatility of the metallic salt, formability of the film, and the like. Examples of the solvent include an alcohol solvent, such as methanol, ethanol, propanol, butanol, pentanol, hexanol, cyclohexanol, methylcellosolve, ethylcellosolve or ethylene glycol; a hydrocarbon solvent, such as hexane, octane, decane, toluene, xylene, mesitylene, ethylbenzene, amylbenzene, decalin, 1-methylnaphthalene, 1-ethylnaphthalen, 1,6-dimethylnaphthalene, or tetralin; a ketone solvent, such as acetone, methyl ethyl ketone, methyl isobutyl ketone, cyclohexanone, acetophenone, propiophenone, or butyrophenone; an ester solvent, such as ethyl acetate, butyl acetate, amyl acetate, acetic acid 2-ethylhexyl, γ-butyrolactone or acetic acid phenyl; and a nitrile solvent, such as acetonitrile or benzonitrile. One kind of the solvent may be used alone or two kinds or more of the solvents may be used in combination.

For example, the organic ligand-containing solution can be prepared by dissolving the above-described organic ligands into a solvent.

The content of the organic ligands in the organic ligand-containing solution is not especially limited, but is, for example, from 1 to 50 mmol/L. The amount of application of the organic ligand-containing solution is not especially limited, but is, for example, from 6×10⁻⁶ to 7×10⁻⁴ μl/μm².

The solvent used for the organic ligand-containing solution is not especially limited and is appropriately selectable considering the kind and the volatility of the organic ligand, formability of the film, and the like. Examples of the solvent can include the ones described as the examples of the solvent used for the metal ion-containing solution.

The application method of the solution is not especially limited, but examples of which include a drop casting method, a casting method, a dip coating method, a die coater method, a roll coater method, a bar coater method, or a spin coating method. The application of the solution can be performed by so-called a printing method, and examples of which include an inkjet method, screen-printing, gravure printing, flexographic printing, offset printing, or microcontact printing. The solution of this embodiment is applied by drop casting method in some embodiments.

The drying method of the solution applied over the substrate is not especially limited, but examples of which include natural drying, drying by heating, drying under reduced pressure, or a combination of these methods. For example, the drying period is from 10 seconds to 1 hour.

The above-described method allows forming the metal organic framework film in this embodiment. In the LBL method, growth of the metal organic framework is generated at the same time in different places on the substrate. This forms the metal organic framework film in which the crystalline structures formed to be developed in the planar direction grow at multiple points.

In this embodiment, the field effect transistor as the manufacturing target may be a bottom-gate and top-contact type. That is, the gate electrode is disposed on the substrate side with respect to the semiconductor layer and the source and drain electrodes are disposed on a side opposite to the substrate with respect to the semiconductor layer (namely, the surface side) in some embodiments. Specifically, the gate electrode is disposed on the substrate, the gate insulating layer is disposed on the gate electrode, the metal organic framework film as the semiconductor layer is disposed on the gate insulating layer, and the source and drain electrodes are disposed on the metal organic framework film in some embodiments. Especially, in this configuration, the gate electrode is made of a metal (aluminum in some embodiments) and the gate insulating layer is made of its metal oxide (aluminum oxide) in some embodiments. The use of the configuration allows uniformly forming the metal organic framework film on the gate electrode. The formation of the source and drain electrodes on the metal organic framework film allows effectively obtaining the field effect transistor that allows low-voltage driving.

### EXAMPLES

The following will describe this embodiment with examples, but the present disclosure is not limited to the examples.

### Example 1

In this example, a metal organic framework film was formed by the following method and evaluated.

(1) Material
Silicon substrate
Copper acetate hydrate
2,3,6,7,10,11-Hexahydroxytriphenylene hydrate (HHTP hydrate)

(2) Formation of Metal Organic Framework Film

First, the silicon substrate was cleaned with a piranha solution. Next, the metal organic framework film was formed on the silicon substrate. The metal organic framework film was formed by repeating 15 times of one cycle including a process of immersing the substrate in an ethanol solution (5 mM) of the copper acetate and cleaning and drying the substrate and a process of immersing the substrate in an ethanol solution (5 mM) of the HHTP hydrate and drying the substrate. Note that the ethanol solution of copper acetate (5 mM) and the ethanol solution of HHTP hydrate (5 mM) were each preliminarily filtered using a PTFE filter of 200 nm. The drying in each process was performed by blowing a nitrogen gas for at least 30 seconds. Through the above-described processes, the metal organic framework film (film thickness: 209±38 nm) was obtained. Metal organic framework films formed by the number of cycles of 5 times, 10 times, or 20 times were also manufactured as a reference, and the film thicknesses was 79±12 nm, 135±21 nm, or 192±40 nm, respectively.

[Evaluations]

(1) Observation with Atomic Force Microscope (AFM), Observation with Field Emission Scanning Electron Microscope (FE-SEM), and Analysis by FT-IR

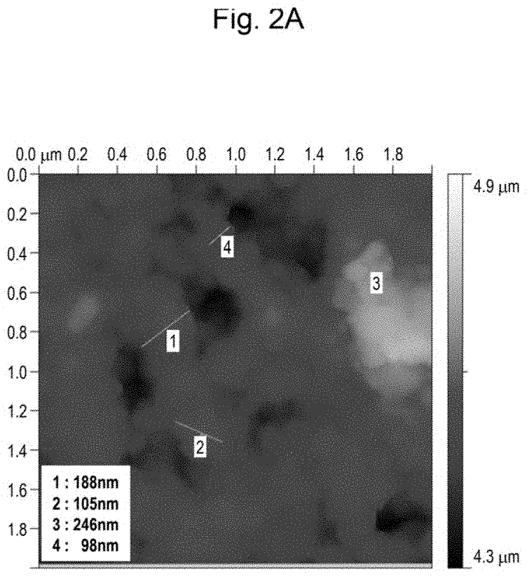

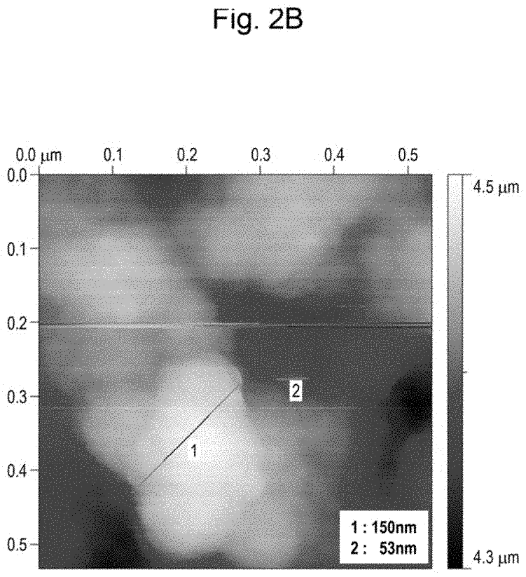

FIG. 2A and FIG. 2B illustrate AFM images of the obtained metal organic framework film. FIG. 2B is an image obtained at a resolution higher than that of the AFM image in FIG. 2A. It is seen from FIG. 2A and FIG. 2B that the metal organic framework film has pores having a diameter of around several hundreds nm.

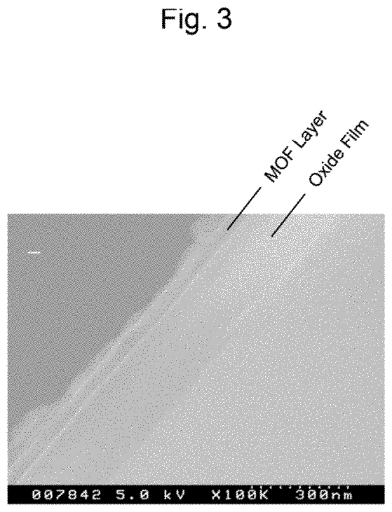

FIG. 3 illustrates an FE-SEM image in which the cross-sectional surface of the obtained metal organic framework film was taken with FE-SEM. It is seen from FIG. 3 that the metal organic framework film (MOF film) is formed.

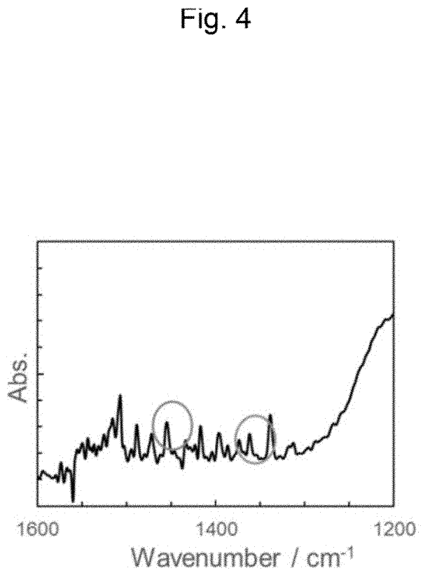

FIG. 4 illustrates results of the analysis of the obtained metal organic framework film by FT-IR. As illustrated in FIG. 4, peaks were observed around 1450 cm⁻¹ indicative of ring stretching and around 1370 cm⁻¹ indicative of C—O stretching. Additionally, in a XRD spectrum (not illustrated) as well, peaks were observed around (100), (200), and (210).

From the above-described results, the formation of the metal organic framework film was confirmed.

(2) I-V Property Evaluation by Four-Terminal Measurement

Four gold electrodes were formed on the surface of the above-described metal organic framework film, and electrical resistances of the metal organic framework film by four-terminal measurement method were evaluated.

σ=(I/V)×(L/WT)[S/cm]

I denotes a current, V denotes a voltage. L denotes a distance between electrodes (the actually measured value: 100 μm), W denotes an electrode width (the actually measured value: 1000 μm), and T denotes a film thickness of the metal organic framework film. T was the average value of the thicknesses at a plurality of positions obtained from the AFM image.

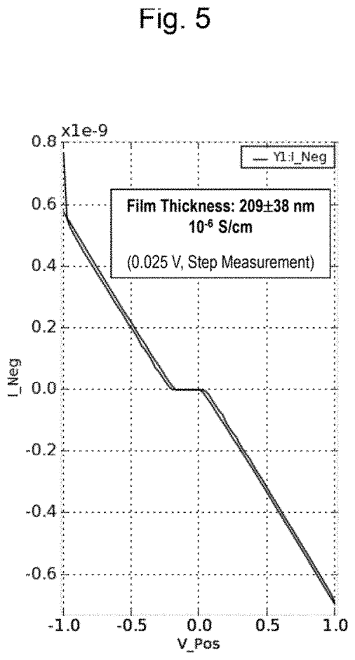

As illustrated in FIG. 5, the linear I-V curved line and a rectification property at around 0 V derived from an ohmic contact were observed. Since a Schottky barrier is present at the semiconductor-metal interface in measurement of the resistance of the semiconductor material, a diode-like property, namely, the rectification property is exhibited at around 0 V. Accordingly, it is seen that the obtained metal organic framework film has the semiconductor property.

### Example 2

### (1) Material

Glass substrate (eagle glass, dimensions: 2×2.5 cm)
Aluminum for vapor deposition (gate electrode)
Gold for vapor deposition (source electrode, drain electrode)
Teflon
Copper acetate hydrate
2,3,6,7,10,11-Hexahydroxytriphenylene hydrate (HHTP hydrate)

(2) Apparatuses
Vacuum deposition apparatus: SVC700TMSG/SVC-7PS80 vacuum evaporator, manufactured by Sanyu Electron Co., Ltd.
Dry etching apparatus: RIE-10NG reactive ion etching system, manufactured by Samco Inc.
Robotic dispenser: Imagemaster 350 dispenser equipment, manufactured by Musashi Engineering, Inc.

(3) Manufacturing Process of (Top-Contact) Field Effect Transistor

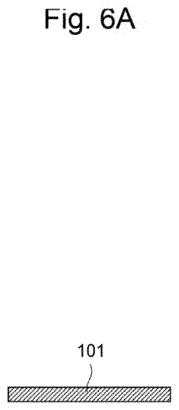

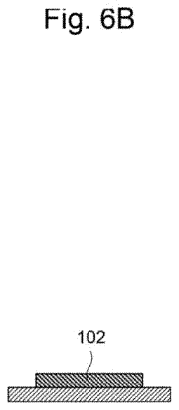

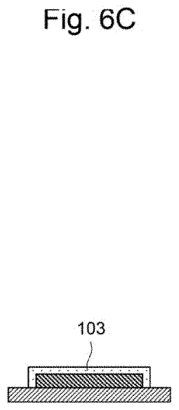

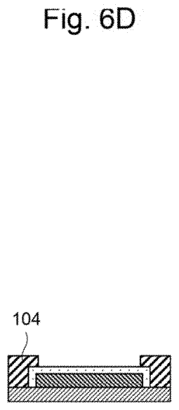

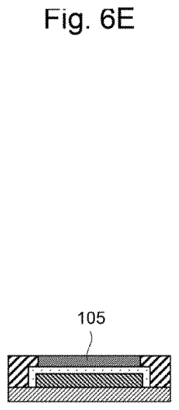

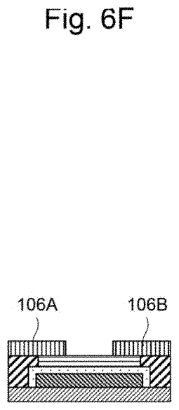

FIG. 6A to FIG. 6F are schematic cross-sectional process drawings for describing the manufacturing process of the (top-contact) field effect transistor in Example 1.

First, as illustrated in FIG. 6A, a glass substrate 101 as the substrate was cleaned with a piranha solution.

Next, as illustrated in FIG. 6B, using the vacuum deposition apparatus using a shadow mask, an aluminum electrode 102 as the gate electrode was vapor-deposited on the glass substrate 101. The aluminum electrode 102 had a thickness of 50 nm.

Next, as illustrated in FIG. 6C, using the dry etching apparatus, a reactive ion etching (RIE) process was performed under conditions of 150 W for five minutes to form an aluminum oxide film 103 as the insulating layer.

Next, as illustrated in FIG. 6D, using the robotic dispenser, a teflon bank 104 to define a region where the semiconductor layer was to be formed was formed.

Next, as illustrated in FIG. 6E, a metal organic framework film 105 as the semiconductor layer was formed. The metal organic framework film 105 was formed by repeating four times of one cycle including a process of repeating performing drop casting of 0.3 μL of an ethanol solution of the copper acetate (5 mM) on the substrate and drying the substrate four times and a process of repeating performing drop casting of 0.3 μL of an ethanol solution of the HHTP hydrate (5 mM) on the substrate and drying the substrate four times. The ethanol solution of copper acetate (5 mM) and the ethanol solution of HHTP (5 mM) were each filtered using a PTFE filter of 200 nm before the drop casting. The drying in each process was performed by leaving the substrate for at least 30 seconds.

Next, as illustrated in FIG. 6F, a source electrode 106A and a drain electrode 106B were formed (channel width/channel length=1000 μm/50 μm) on the metal organic framework film 105 by vacuum deposition using the shadow mask. Gold was used for the source electrode 106A and the drain electrode 106B.

Through the above-described processes, a top-contact field effect transistor E1 was obtained.

### Example 3

In Example 3, a metal organic framework film was formed using 1,3,5-benzenetricarboxylic acid (BTC) as the organic ligand. Specifically, except that a forming process of the metal organic framework film as the semiconductor layer illustrated in FIG. 6E was performed by the method described below, a top-contact field effect transistor E2 was obtained by the method similar to Example 2.

In the forming process of the metal organic framework film as the semiconductor layer illustrated in FIG. 6E, the metal organic framework film 105 was formed by repeating 16 times of one cycle including a process of performing drop casting of 0.2 μL of an ethanol solution of the copper acetate (1 mM) on the substrate and drying the substrate and a process of performing drop casting of 0.2 μL of an ethanol solution of the BTC (1 mM) on the substrate and drying the substrate. The ethanol solution of copper acetate (1 mM) and the ethanol solution of BTC (1 mM) were each filtered using a PTFE filter of 200 nm before the drop casting. The drying in each process was performed by leaving the substrate for at least 30 seconds.

### Comparative Example 1

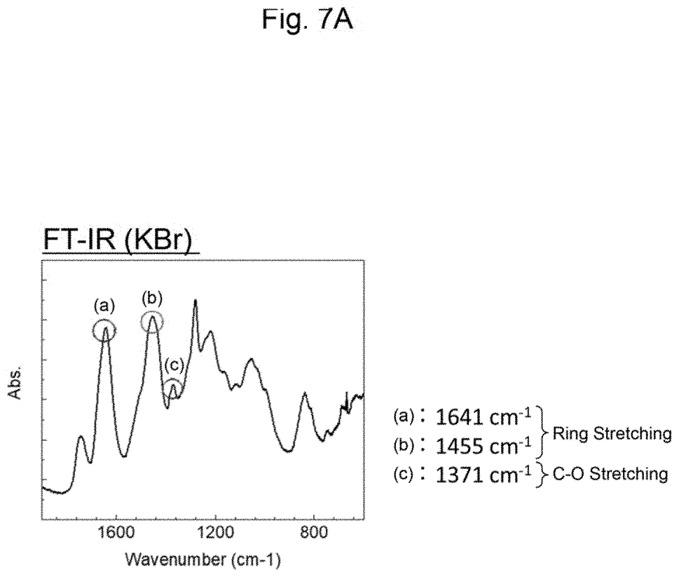

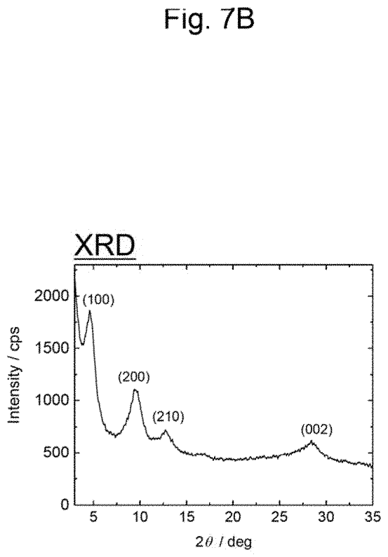

The HHTP hydrate and the copper acetate were mixed in methanol and reacted at 65° C. for 24 hours to form particulate metal organic frameworks. FIG. 7A illustrates a FT-IR spectrum and FIG. 7B illustrates a XRD spectrum of the obtained particulate MOFs. It is seen from FIG. 7A and FIG. 7B that the particulate metal organic frameworks made of the HHTP and the copper ions were obtained.

Using the obtained particulate MOFs, a top-contact field effect transistor C1 was formed in accordance with the processes described in Example 2 other than the process of forming the metal organic framework film. Specific processes will be described below.

First, as illustrated in FIG. 6A as a reference, a glass substrate as a substrate was cleaned with a piranha solution.

Next, as illustrated in FIG. 68 as a reference, using the vacuum deposition apparatus using a shadow mask, an aluminum electrode as the gate electrode was vapor-deposited on the glass substrate. The aluminum electrode had a thickness of 50 m.

Next, as illustrated in FIG. 6C as a reference, using the dry etching apparatus, a reactive ion etching (RIE) process was performed under conditions of 150 W for five minutes to form an aluminum oxide film as the insulating layer.

Next, as illustrated in FIG. 6D as a reference, using the robotic dispenser, a teflon bank to define a region where the semiconductor layer was to be formed was formed.

Next, as illustrated in FIG. 6E as a reference, using the particulate MOFs, a layer formed of the metal organic framework was formed. The layer of the metal organic framework was formed by performing drop casting of an aniline solution of particulate MOFs (0.16 weight %) by an amount of 0.25 μL on the substrate and drying the substrate.

Next, as illustrated in FIG. 6F as a reference, a source electrode and a drain electrode were formed (channel width/channel length=1000 μm %50 μm) on the layer of the metal organic framework film by vacuum deposition using the shadow mask. Gold was used for the source electrode and the drain electrode.

Through the above-described processes, the field effect transistor C1 was obtained.

### Comparative Example 2

### (1) Material

Silicon substrate (dimensions: 2×2.5 cm)
Gold for vapor deposition (source electrode, drain electrode)
Teflon
Copper acetate hydrate
2,3,6,7,10,11-Hexahydroxytriphenylene hydrate (HHTP hydrate)
2,3,5,6-tetrafluoro-4-mercaptobenzoic acid (TFMBA)

Since the TFMBA has a binding site with gold and a binding site with copper ions, the TFMBA was used to ensure adhesiveness between the metal organic framework film and the gold electrodes.

(2) Apparatuses
Vacuum deposition apparatus: SVC700TMSG/SVC-7PS80 vacuum evaporator. manufactured by Sanyu Electron Co., Ltd.
Dry etching apparatus: RIE-10NG reactive ion etching system, manufactured by Samco Inc.
Robotic dispenser: Imagemaster 350 dispenser equipment, manufactured by Musashi Engineering, Inc.

(3) Manufacturing Process of (Bottom-Contact) Field Effect Transistor

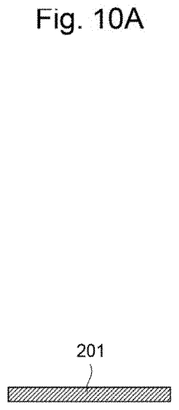

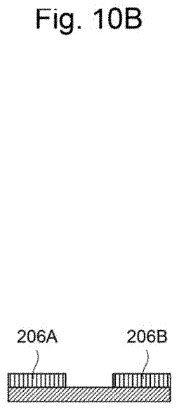

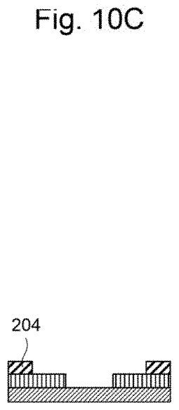

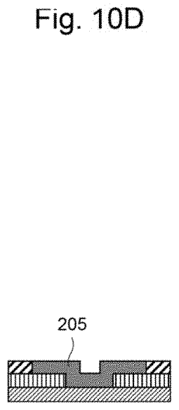

FIG. 10A to FIG. 10D are schematic cross-sectional process drawings for describing the manufacturing process of the (bottom-contact) field effect transistor in Comparative Example 2.

First, as illustrated in FIG. 10A, a silicon substrate 201 as the substrate was cleaned with a piranha solution.

Next, as illustrated in FIG. 10B, a source electrode 206A and a drain electrode 206B were formed using the vacuum deposition apparatus using the shadow mask. Gold was used for the source electrode 206A and the drain electrode 206B. The electrodes each had a thickness of 50 nm. A substrate on which gold was vapor-deposited was immersed in a TFMBA solution (10 mM) produced by dissolving the TFMBA into 2-propanol for 10 minutes to perform a TFMBA process. After the immersion, the substrate was cleaned with 2-propanol, and nitrogen blowing was performed.

Next, as illustrated in FIG. 10C, using the robotic dispenser, a teflon bank 204 to define a region where the semiconductor layer was to be formed was formed.

Next, as illustrated in FIG. 10D, a metal organic framework film 205 as the semiconductor layer was formed. The metal organic framework film 205 was formed by repeating seven times of one cycle including a process of performing drop casting of 3 μL of an ethanol solution of the copper acetate (50 mM) on the substrate and drying the substrate and a process of performing drop casting of 3 μL of an ethanol solution of the HHTP hydrate (50 mM) on the substrate and drying the substrate. Note that the ethanol solution of copper acetate (50 mM) and the ethanol solution of HHTP (50 mM) were each filtered using a PTFE filter of 200 nm before the drop casting. The drying in each process was performed by leaving the substrate for at least five minutes.

By the above-described processes, the bottom-contact field effect transistor C2 was obtained. Note that in the field effect transistor C2, the silicon has a function of a gate electrode, and a silicon oxide film has a function of an insulating layer.

[Evaluation]

### (1) Transmission Characteristics and Output Characteristics

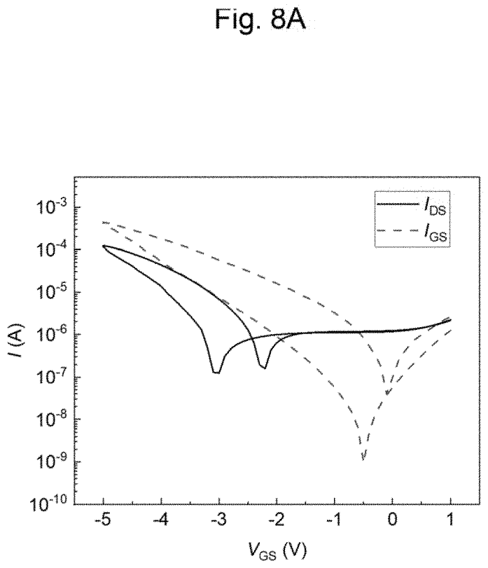

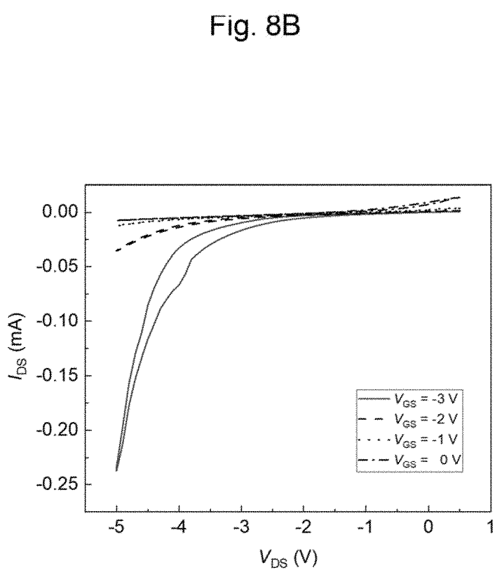

The transmission characteristics and/or the output characteristics of the manufactured field effect transistors E1, E2, C1, and C2 were evaluated in the atmosphere using a source meter (manufactured by Keithley Instruments). Specifically, the evaluations were performed as follows. The current and the voltage were measured by bringing a short needle of a probe in contact with the gate electrode, the source electrode, and the drain electrode. The transmission characteristics are indicated by a correlation relation between a gate voltage (V_{GS}) and a drain current (I_{DS}) obtained when a drain voltage is set to be constant via the source meter and the gate voltage (V_{GS}) is swept while being modulated (for example, FIG. 8A). The output characteristics are indicated by a correlation relation between a drain voltage and a drain current obtained when a gate voltage is set to be constant and the drain voltage (V_{DS}) is modulated and swept (for example, FIG. 8B). At that time, both sources are constantly grounded. In the measurement, the gate voltage of −5 V or less, which is a voltage lower than the applied voltage of the ordinary organic transistor, was applied. Regarding the output characteristics, the output characteristics with V_{GS} of 0, −1, −2, and −3 V were measured.

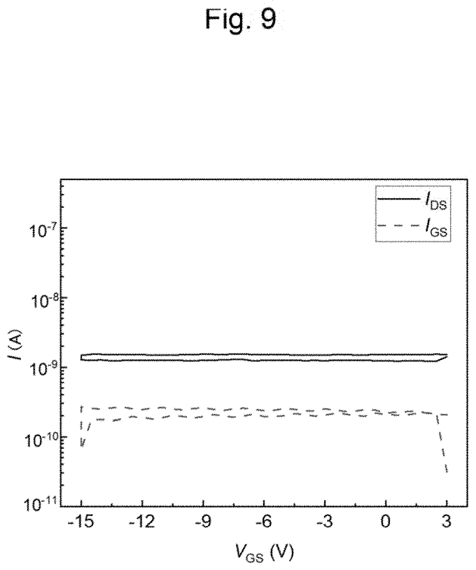

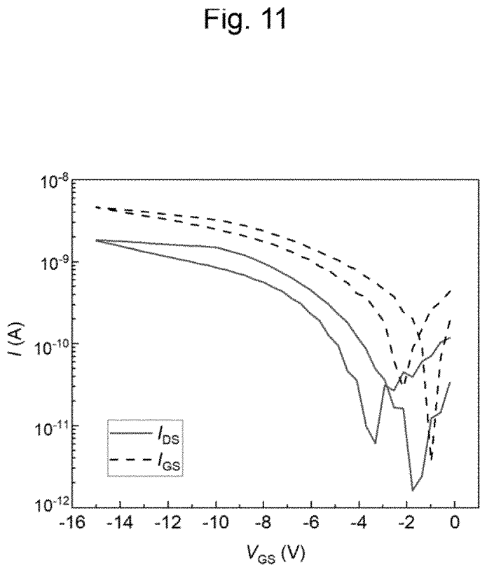

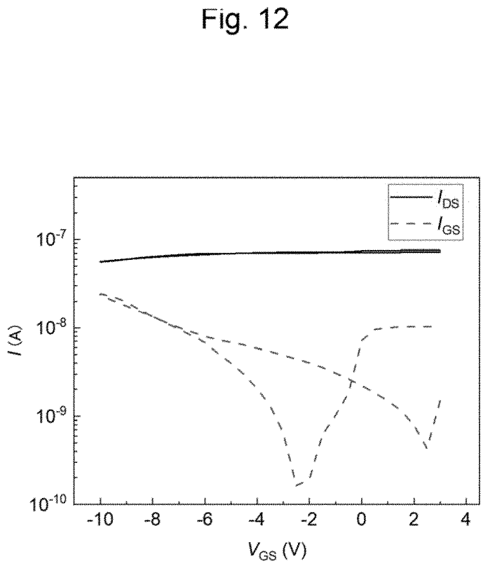

FIG. 8A is a graph illustrating results of the evaluation of the transmission characteristics of the field effect transistor E1 (Example 2). FIG. 8B is a graph illustrating results of the evaluation of the output characteristics of the field effect transistor E1 (Example 2). FIG. 9 is a graph illustrating results of the evaluation of the transmission characteristics of the field effect transistor C1 (Comparative Example 1). FIG. 11 is a graph illustrating results of the evaluation of the transmission characteristics of the field effect transistor E2 (Example 3). FIG. 12 is a graph illustrating results of the evaluation of the transmission characteristics of the field effect transistor C2 (Comparative Example 2).

As illustrated in FIG. RA, it was confirmed that, in the transmission characteristics, rising of the ON current was observed at around −2.5 V, and the field effect transistor E1 exhibited satisfactory FET characteristics. Regarding the output characteristics as well, the FET characteristics according to the applied voltage was obtained (FIG. 8B). Usually, since the organic semiconductor material is unstable in the atmosphere, the transmission characteristics and the output characteristics are generally evaluated under a nitrogen atmosphere. However, the field effect transistor obtained in this example exhibited the stable transistor characteristics in the atmosphere even without performing a special process, such as use of sealing agent. Additionally, as understood from FIG. 8A and FIG. 88, driving at a low-voltage of 5 V or less was confirmed. As illustrated in FIG. 11, a nonlinear drain current value increase was observed.

Meanwhile, as understood from FIG. 9, the field effect transistor C1 of Comparative Example 1 did not exhibit the semiconductor property. Additionally, as understood from FIG. 12, the field effect transistor C2 of Comparative Example 2 did not exhibit the semiconductor property as well. Note that the transistor characteristics have a feature in change in a current switched from off to on in association with the application of the gate voltage. The characteristics were not observed from the graph of FIG. 12, and therefore it was determined that the transistor characteristics were not obtained. The following reason is inferred as the reason that the field effect transistors of the comparative examples did not exhibit the semiconductor property. With the bottom-contact type, the metal organic framework film needs to be formed with a channel (between the source and the drain) having a fine space. However, the adhesiveness between the electrodes and the metal organic framework film in the bottom-contact type is lower than that of the top-contact type. It is inferred that the transistor characteristics were not obtained in the bottom-contact type because of this reason. Note that the above-described inference does not limit the present disclosure.

(2) Evaluation as Gas Sensor

As a gas sensing evaluation device, a compact glove box for gas sensing evaluation was designed with the cooperation of UNICO LTD. The glove box includes a flange on its back surface, thereby allowing evaluation for transistor characteristics under the gas atmosphere. At that time, the transistor was evaluated with self-produced connector and source meter coupled via the flange. A flow rate of the gas was adjusted using a Permeater (manufactured by GASTEC CORPORATION). The Permeater allows achieving the quantitative gas flow rate. Examples of the gas component as the detection target include ammonia, ethanol, acetone, n-decane, n-dodecane, ethylbenzene, toluene, acetaldehyde, phenol, or propylamine.

Gas sensing ability of the field effect transistor E1 (Cu-HHTP MOF) obtained in Example 1 was evaluated using the gas sensing evaluation device. Specifically, the field effect transistors were disposed in the glove boxes, an ammonia gas was injected into the glove box each so as to be a predetermined concentration, and the electrical resistance after five minutes was measured by the above-described four-terminal measurement method. Table 1 shows the results.

TABLE 1

| Ammonia concentration (ppm) | Electrical resistance (S/cm) |
|---|---|
| 0 | 1.85 × 10⁻⁵ |
| 0.5 | 1.73 × 10⁻⁵ |
| 1.0 | 1.58 × 10⁻⁵ |
| 14 | 1.54 × 10⁻⁵ |
| 50 | 1.50 × 10⁻⁵ |

As shown in Table 1, the field effect transistor E1 exhibits a different electrical resistance according to a concentration of an ammonia gas, and it is seen that exhibits a change in conductive property of the MOF depending on the concentration of the ammonia gas. Accordingly, it was confirmed that the field effect transistor of this embodiment had the gas sensing capability.

Upper limit values and/or lower limit values of respective numerical ranges described in this specification can be appropriately combined to specify an intended range. For example, upper limit values and lower limit values of the numerical ranges can be appropriately combined to specify an intended range, upper limit values of the numerical ranges can be appropriately combined to specify an intended range, and lower limit values of the numerical ranges can be appropriately combined to specify an intended range.

While the embodiment has been described in detail, the specific configuration is not limited to the embodiment. Design changes within a scope not departing from the gist of the disclosure are included in the present disclosure.

What is claimed is:

1. A field effect transistor comprising:
a substrate;
a source electrode;
a drain electrode;
a gate electrode; and
a metal organic framework film as a semiconductor layer,
wherein the metal organic framework film has a stacked structure, a plurality of crystalline structures in which organic ligands having a π-conjugated skeleton and metal ions are coordinated to be developed in a planar direction of the substrate are stacked on the substrate via a π-π interaction in the stacked structure,
wherein the crystalline structures each have pores formed by the coordination of the organic ligands and the metal ions, and the pores in the adjacent crystalline structures communicate with one another in a film thickness direction in the stacked structure, and
wherein the field effect transistor is a top-contact type.

2. The field effect transistor according to claim 1,
wherein the field effect transistor is a bottom-gate and top-contact type.

3. The field effect transistor according to claim 1,
wherein the π-conjugated skeleton includes at least one aromatic ring.

4. The field effect transistor according to claim 1,
wherein the π-conjugated skeleton has a polycyclic aromatic hydrocarbon structure.

5. The field effect transistor according to claim 1,
wherein the organic ligand has a three-fold rotational symmetry.

6. The field effect transistor according to claim 1,
wherein the metal ions are metal ions capable of having a coordination number of four or more.

7. The field effect transistor according to claim 1,
wherein the gate electrode is an aluminum electrode.

8. The field effect transistor according to claim 7,
wherein the aluminum electrode has a surface on which an aluminum oxide as a gate insulating layer is formed.

9. The field effect transistor according to claim 1,
wherein the metal organic framework film is formed by a LBL method, and the LBL method includes applying a metal ion-containing solution containing the metal ions over the substrate and applying an organic ligand-containing solution containing the organic ligands over the substrate.

10. A gas sensor comprising
the field effect transistor according to claim 1.

11. A method of manufacturing the field effect transistor according to claim 1, the method comprising
forming the metal organic framework film by LBL method including:
applying a metal ion-containing solution containing the metal ions over the substrate; and
applying an organic ligand-containing solution containing the organic ligands over the substrate.
